(19) United States
(12) Patent Application Publication
(10) Pub. No.: US 2002/0117700 A1
(43) Pub. Date: Aug. 29, 2002

(54) Amorphous iridium oxide barrier layer and electrodes in ferroelectric capacitors

(76) Inventor: Glex Fox, Colorado Springs, CO (US)

Correspondence Address: William J. Kubida, Esq., Hogan & Hartson, LLP, 1200 17th Street, Suite 1500, Denver, CO, 80202, US

(21) Appl. No.: 09/796,998

(22) Filed: Feb. 28, 2001

(51) Int. Cl. H01L 29/76

(52) U.S. Cl. 257/295

(57) ABSTRACT

A method for the fabrication of a layer of amorphous iridium oxide (IrOₓ) in a ferroelectric capacitor is described. The amorphous iridium oxide layer may act as a top electrode of the ferroelectric capacitor, or may be deposited on a top electrode that is made from crystalline iridium oxide or some other conductive material. The amorphous iridium oxide layer protects the underlying ferroelectric dielectric layer from chemical and mechanical degradation. Specifically, the amorphous iridium oxide layer is thought to act as a barrier against hydrogen, that reacts with the ferroelectric material in the ferroelectric dielectric layer and degrades the performance of the ferroelectric capacitor.

### FIELD OF THE INVENTION

This invention relates to the field of ferroelectric memory integrated circuit processing. In particular, the invention relates to forming the electrodes of ferroelectric capacitors, that are used in ferroelectric memory cells, from amorphous iridium oxide (IrOₓ).

### BACKGROUND OF THE INVENTION

The potential of Ferroelectric Random Access Memory (FRAM) as the preferred memory technology for handheld electronic devices like cellular telephones, Personal Digital Assistants (PDAs), and digital cameras has long been recognized: FRAM is a nonvolatile memory technology that does not lose data when power is shut off. In contrast, the data stored in the volatile DRAM memory used in most desktop and notebook computers is lost when the computer is shut down. These computers require an additional component, such as a bulky and delicate hard disk drive, to retain data between power ups. Thus, FRAM helps keep handheld devices small and durable by eliminating the need for additional, nonvolatile data storage components.

FRAM has several advantages over other nonvolatile memory technologies such as Electrically Erasable, Programmable Read Only Memory (EEPROM) and Flash EEPROM. EEPROM and Flash EEPROM tend to have short read times, ranging between nanoseconds and microseconds, but write times on the order of milliseconds. The several orders of magnitude difference between read and write times, combined with the block-erase character of Flash EEPROM, can complicate the design and use of EEPROM and Flash EEPROM devices. In contrast, FRAM can execute both read and write operations in less than one microsecond.

FRAM also has excellent endurance characteristics: the useable lifetime of FRAM memory cells can extend to more than a trillion (10¹²) read/write cycles. Such strong resistance to read/write cycle fatigue makes FRAM well suited for devices like portable computers that execute hundreds of millions to billions of operations per second.

FRAM memory cells are formed by capacitors such that data is accessed by manipulating the voltage and/or current applied to electrodes of the capacitors. The capacitors in FRAM memory cells use ferroelectric compounds to separate the electrodes. Ferroelectric compounds commonly used in FRAM include oxides with a perovskite crystal structure such as lead titanate zirconate—Pb(ZrₓTi₁₋ₓ)O₃—commonly referred to as PZT, and strontium bismuth titanate—SrBiTiO—commonly referred to as SBT. These ferroelectric dielectric materials are integrated with other semiconductor devices to provide circuitry for addressing, selection, and control logic. Unfortunately, the desired electrical characteristics of many ferroelectric materials, such as data retention and resistance to fatigue, are degraded under typical semiconductor processing conditions. Thus, semiconductor device manufacturers face continual difficulty in preserving the high quality electrical characteristics of ferroelectric materials when integrating FRAM memory cells with standard semiconductor production and packaging processes.

One of the primary reasons for the degradation of FRAM during processing is believed to be the reaction of oxygen atoms in the ferroelectric material with gases such as hydrogen. Hydrogen exposure occurs during cleaning operations like plasma ashing to remove photoresists. Also, metal deposition processes often incorporate hydrogen through the use of organometallic compounds and/or the use of hydrogen to treat formed metal structures. Moreover, it is common in semiconductor-manufacturing processes to remove excess material after a deposition by Chemical Mechanical Polishing (CMP). While CMP is effective for removing excess materials such as tungsten, the chemical reactions and mechanical agitation are also believed to drive hydrogen into the ferroelectric layer and damage the PZT. Consequently, the resulting FRAM produced has much poorer and inconsistent quality than desired.

### SUMMARY OF THE INVENTION

The present invention is directed to an integrated circuit and methods for making an integrated circuit that include ferroelectric components integrated with other semiconductor devices that provide improved performance and greater process latitude. The present invention provides for forming a layer of amorphous iridium oxide (IrOₓ) in order to protect the underlying layer (or layers) of ferroelectric materials from chemical degradation. Specifically, the iridium oxide top electrode of the present invention protects underlying layers of ferroelectric materials, such as PZT, from degradation by hydrogen and other reduction gases.

In accordance with the present invention there is provided an integrated semiconductor device that comprises a ferroelectric capacitor. In a preferred embodiment, the top electrode is originally formed from a layer of amorphous iridium oxide that is subsequently annealed into a crystalline structure. In another preferred embodiment, the top electrode comprises two layers of iridium oxide, where a lower layer is formed from crystalline iridium oxide, and an upper layer is formed from amorphous iridium oxide. In yet another preferred embodiment, the amorphous iridium oxide layer is formed over the top electrode, and the top electrode is made from an electrode material such as platinum, iridium, ruthenium oxide (RuO₂), strontium ruthenium oxide (SrRuO₃), LaSrCoO₃, and LaNiO₃. In all of these preferred embodiments, the amorphous iridium oxide protects the ferroelectric dielectric layer of the capacitor from chemical and mechanical degradation during semiconductor fabrication processes.

Further in accordance with the present invention, there is also provided a method for forming an iridium oxide top electrode of a ferroelectric capacitor in an integrated semiconductor device. This method provides for using amorphous iridium oxide to form some, or all, of the top electrode. The iridium oxide top electrode formed by the method of the present invention provides the underlying ferroelectric dielectric layer with excellent protection from mechanical and chemical degradation during subsequent device fabrication steps.

The ferroelectric capacitor structure provided by the present invention is more robust in the face of subsequent temperature and chemical exposure during annealing, cleaning, multi-layer metal processing, interconnect processing and assembly. Moreover, the adverse impact of processes subsequent to fabrication of the capacitor structures is reduced, enabling a wider variety of processes to be performed subsequent to fabrication and thereby enabling new devices with higher levels of integration to be achieved without compromising the performance of the ferroelectric devices.

### BRIEF DESCRIPTION OF THE DRAWINGS

FIG. 1 is a cross section of a ferroelectric capacitor on a semiconductor circuit fabricated according to the present invention;

FIG. 2 is a graph of the intensity of Ir (111) and IrO₂ (110) XRD peaks as a function of the O₂ flow rate in the amorphous iridium oxide sputtering example;

FIG. 3 is a graph of the biaxial stress in the iridium oxide layer as a function of the O₂ flow rate in the amorphous iridium oxide sputtering example;

FIG. 4 is a graph of the intensity of the IrO₂ (110) XRD peak as a function of the sputtering power in the amorphous iridium oxide sputtering example; and

FIG. 5 is a drawing of a top IrOx top electrode layer after anneal, according to the present invention. The amorphous structure transforms into a polycrystalline structure that has equiaxed grains of less than 30 nm.

### DETAILED DESCRIPTION OF THE INVENTION

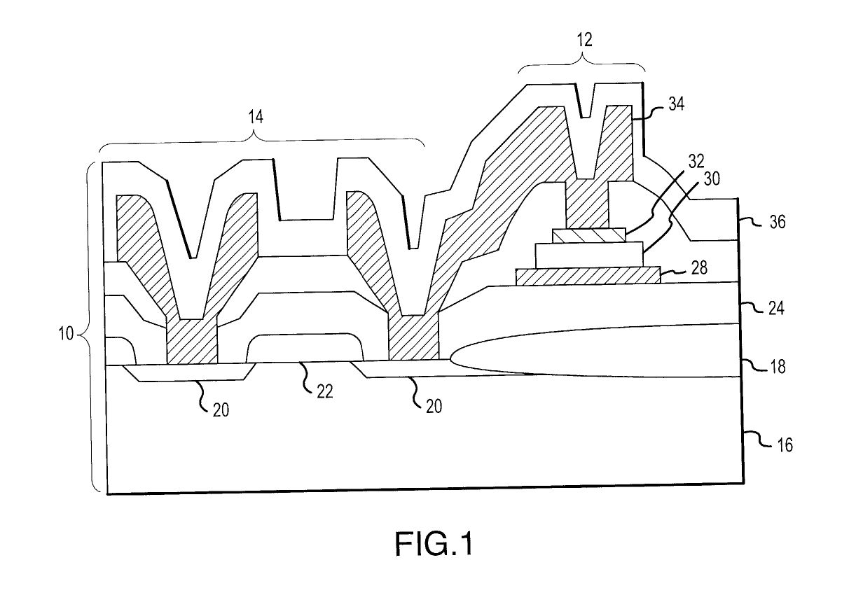

Referring now to FIG. 1, an example of an integrated ferroelectric memory cell 10 incorporated into an integrated semiconductor device of the present invention is shown. The integrated ferroelectric cell 10 includes a ferroelectric capacitor 12, as well as a field-effect transistor (“FET”) 14. In the embodiment of FIG. 1, the ferroelectric memory cell 10 is configured as a one transistor, one capacitor (“1T-1C”) memory cell. The memory cell 10 includes a substrate or epitaxial layer 16, a thick field oxide layer 18, diffused areas 20 for forming the drain and source regions of the transistor 14, a gate electrode 22 that is coupled to, or forms a portion of, a word line (extending orthogonal to the plane of FIG. 1 and therefore not shown). Planarization layer 24 comprises an insulating material such as an oxide that is applied in a thick layer and planarized using chemical, mechanical, chemical mechanical polishing, or the like to provide a flat working surface for overlying device structures.

In a preferred embodiment, an adhesion layer (not shown) lies between the ferroelectric capacitor 12 to the planarization layer 24, in order to enhance the adhesion of the ferroelectric capacitor 12 to the rest of the integrated semiconductor device. The adhesion layer (not shown) is preferably made of titanium oxide with a thickness of 50 Å to 200 Å, although thinner and thicker layers are suitable when they demonstrate adhesion.

The capacitor 12 is formed with a bottom electrode 28, a ferroelectric dielectric layer 30, and a top electrode layer 32. The bottom electrode layer 28 is preferably fabricated of platinum, and has a thickness of 500 Å to 2000 Å, more preferably 1750 Å, although thinner and thicker layers are suitable when they demonstrate good electrode characteristics in an integrated semiconductor device. The bottom electrode 28 is connected to a “plate line” that is in turn coupled to a plurality of memory cells. The plate line is also orthogonal to the plane of FIG. 1, and therefore not shown.

The ferroelectric dielectric layer 30 preferably comprises an oxide with a perovskite crystal structure such as lead titanate zirconate—Pb(ZrₓTi₁₋ₓ)O₃, (i.e., PZT) or strontium bismuth titanate—SrBiTiO (i.e., SBT). The ferroelectric dielectric layer 30 preferably has a thickness of 1000 Å to 2500 Å, more preferably a thickness of approximately 1800 Å, although thinner and thicker layers are suitable when they demonstrate good ferroelectric qualities in an integrated semiconductor device.

In this preferred embodiment, the top electrode layer 32 is formed from a single layer of amorphous iridium oxide. The average grain size of the amorphous iridium oxide deposited is preferably 100 nm or less. The top electrode layer 32 preferably has a thickness of 500 Å to 2000 Å, and more preferably a thickness of about 1500 Å, although thinner and thicker layers are suitable when they demonstrate good electrode characteristics in an integrated semiconductor device. The amorphous iridium oxide may be crystallized by subsequent annealing in order to improve the electrical conductivity of the top electrode.

In another preferred embodiment (not shown), the top electrode layer 32 comprises two or more layers, at least one of which is formed from amorphous iridium oxide. In this embodiment, a high conductivity layer (not shown) is formed on top of the ferroelectric dielectric layer 30, and then an amorphous iridium oxide layer is formed on top of the high conductivity layer. The high conductivity layer can be formed from a variety of conductive materials, including crystalline iridium oxide, platinum, iridium, ruthenium oxide (RuO₂), strontium ruthenium oxide (SrRuO₃), LaSrCoO₃, and LaNiO₃.

The top electrode layer 32 is coupled to the source region of the transistor 14 via a metalization layer 34. Metalization layer 34 also contacts the drain of transistor 14, forming the bit line contact. In a preferred embodiment, a passivation layer 36 may be subsequently deposited over the entire surface of the integrated circuit.

Turning now to the method of the present invention, the method comprises the steps of: Forming a top electrode comprising amorphous iridium oxide on top of a ferroelectric dielectric layer; and annealing the top electrode in an oxidizing atmosphere in order to crystallize the top electrode. The average grain size of the amorphous iridium oxide deposited is preferably 100 nm or less. In a preferred aspect of the present method, one or more additional process step may occur between the initial formation and annealing of the top electrode. For example, etching steps, where the top electrode layer, ferroelectric dielectric layer, and/or the bottom electrode layer are etched into the structure used in the integrated semiconductor device, may occur before the top electrode is annealed.

Another embodiment of the method of the present invention comprises the steps of: Forming a conductive layer on top of a ferroelectric dielectric layer of a ferroelectric capacitor; and forming a layer comprising amorphous iridium oxide on top of the conductive layer, wherein the conductive layer and the layer comprising amorphous iridium oxide comprise a top electrode of the ferroelectric capacitor. In this preferred method, the conductive layer is formed from conductive materials that include crystalline iridium oxide, platinum, iridium, ruthenium oxide (RuO₂), strontium ruthenium oxide (SrRuO₃), LaSrCoO₃, and LaNiO₃.

The method of forming the amorphous iridium oxide top electrode of the present invention may be incorporated into conventional methods for forming integrated semiconductor devices. For example, the bottom electrode of a ferroelectric capacitor is formed on a substrate layer of the integrated semiconductor device. In a preferred embodiment, the bottom electrode is formed with a laminated structure that comprises an adhesion layer, in contact with the underlying substrate layer and a bottom electrode layer, lying on top of the adhesion layer. The lower layer preferably comprises titanium oxide formed by depositing titanium (Ti) metal on the substrate layer, and heating the metal layer in an oxygen atmosphere, at 300° C. to 700° C. The bottom electrode layer preferably comprises a conductive metal or metal oxide, and more preferably comprises platinum. The bottom electrode layer can be formed on the adhesion layer through any number of standard deposition techniques, such as DC sputtering.

Following the formation of the bottom electrode layer, the ferroelectric dielectric layer is formed on the bottom electrode. The ferroelectric dielectric layer is made from a ferroelectric material that preferably comprises an oxide with a perovskite crystal structure such as lead titanate zirconate—PZT, or strontium bismuth titanate—SBT. In a preferred aspect of the present invention the ferroelectric dielectric material is PZT that preferably may be doped with a metal selected from the group consisting of lanthanum, calcium or strontium. Preferably, RF sputtering or a sol-gel process is used to deposit the ferroelectric material on the bottom electrode. Once the ferroelectric dielectric layer is formed, heating in a non-reducing atmosphere is preferably performed to crystallize the ferroelectric material. For example, the ferroelectric material may be crystallized through a Rapid Thermal Anneal (RTA) process.

After the formation of the ferroelectric dielectric layer, a top electrode is formed that comprises, at least in part, a layer of amorphous iridium oxide material. A preferred method for forming the amorphous iridium oxide layer comprises the steps of flowing a mixture of argon and oxygen (O₂) gases across an iridium metal sputtering target; bombarding the sputtering target with argon ions in order to sputter iridium off the target; and depositing the layer of amorphous iridium oxide (IrOₓ) over the previously deposited layer of the ferroelectric capacitor. In one preferred embodiment, the previously deposited layer is the ferroelectric dielectric layer, and the amorphous iridium oxide layer ultimately forms the top electrode of the capacitor. In another preferred embodiment, the previously deposited layer is the top electrode, and the amorphous iridium oxide layer forms a protective layer over the top electrode of the capacitor.

After the top electrode is deposited on the ferroelectric dielectric layer, an annealing step is preferably performed that is of sufficient duration and temperature to for the grain growth of the PZT in the ferroelectric dielectric layer to be complete. Typically, this anneal is performed at about 650° C. in an atmosphere comprising a partial pressure of oxygen that is preferably 1% to 5% with the balance of the atmosphere comprising inert gases such as argon, neon, helium or xenon.

Following the formation of the amorphous iridium oxide layer, a wide variety of integrated semiconductor fabrication processes are employed to produce the integrated semiconductor devices of the present invention. These processes include chemical etching and cleaning, ILD, CMP, and rejuvenating anneals, among others.

The processes described here preferably use sputter deposition for depositing the various layers of materials that comprise the capacitor stack. It is expected that the process may function with other methods of deposition, including Chemical Vapor Deposition (“CVD”), and solution chemistry deposition, so called “spin on” techniques, as appropriate for the various layers, and as known in the art.

### EXAMPLES

### Example 1

The ferroelectric capacitor used in the following example includes substrate layer, an adhesion layer lying on top of the substrate layer, a bottom electrode lying on top of the adhesion layer, a ferroelectric dielectric layer on top of the bottom electrode, and a top electrode on top of the ferroelectric dielectric layer. The substrate layer comprises silicon dioxide with a 5000 Å thickness. The adhesion layer is formed from titanium with a 200 Å thickness. The bottom electrode is formed from platinum with a 1750 Å thickness. The ferrolectric dielectric layer is formed from a PZT bilayer with a thickness of 2200 Å. The formation of the ferroelectric dielectric layer also included a two stage rapid thermal anneal, with the first stage lasting for 90 seconds at 600° C. in and argon/oxygen atmosphere, and the second stage lasting for twenty seconds at 725° C. in an oxygen atmosphere.

The top electrode was formed by sputtering an iridium metal target in a mixture of argon and oxygen (O₂). The sputtering tool used was the commercially available ZX-1000. The argon and oxygen flow rates are set close to the iridium metal-to-oxide sputtering transition, when the surface of the iridium metal target is oxidized. If the oxygen flow rate is too low, sputtering deposits films mostly comprising iridium metal as the top electrode. If the flow rate is too high, the iridium oxide (IrOₓ) deposited is too crystalline.

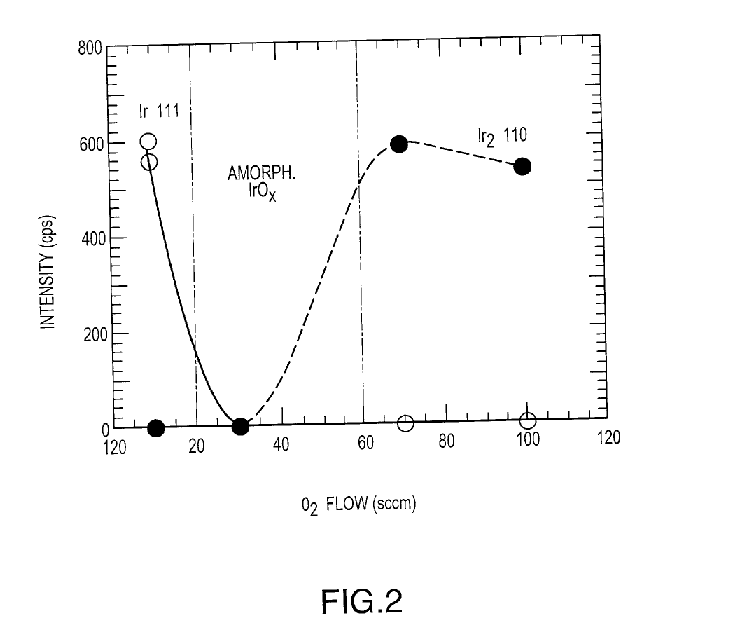

The results of X-ray diffraction (“XRD”) measurements of the crystallinity of the iridium oxide deposited as the top electrode is shown in FIG. 2. In this example, the sputtering power was fixed at 1 kW and the argon gas flow rate was fixed at 100 sccm. Based on FIG. 2, amorphous iridium oxide is deposited as the top electrode when the O₂ flow rates are 20 sccm to 60 sccm, with 20 sccm representing the O₂ flow rate where the metal-to-oxide transition occurs.

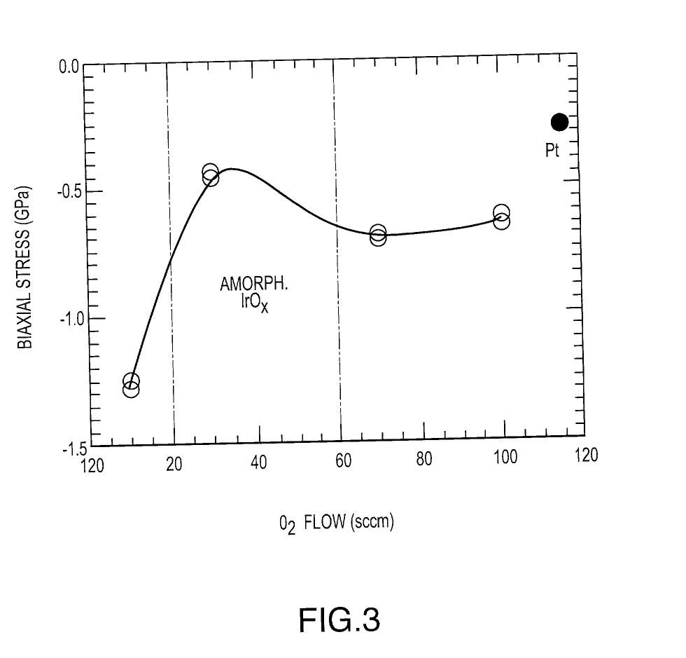

FIG. 3 charts the amount of biaxial stress in the amorphous iridium oxide top electrode that is formed under the same sputtering conditions as described for FIG. 2 above. Increased biaxial stress in the top electrode has been shown to degrade the electrical properties of a ferroelectric capacitor, such as the polarization switching charge (Q_{SW}), leakage current from the ferroelectric material, and the voltage level required to switch the polarity of 90% of material in the ferroelectric dielectric layer (V_{90%}). Thus, minimizing biaxial stress in the top electrode layer improves the electrical characteristics of ferroelectric capacitors used in FRAM memory cells and other integrated semiconductor devices of the present invention. The graph in FIG. 3 shows that biaxial stress is minimized when the O₂ gas flow rate was approximately 30 sccm.

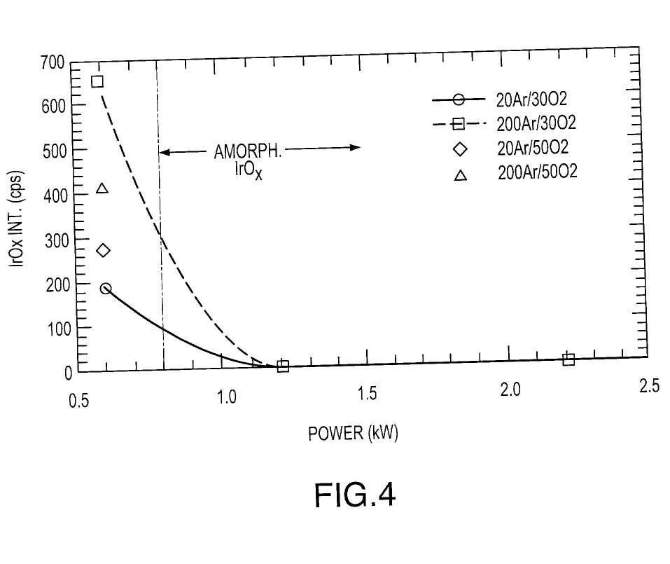

In addition to the O₂ gas flow rate, the power applied to the iridium metal sputtering target also important in controlling the formation of amorphous iridium oxide. When the power drops below 0.8 kW, the iridium oxide deposited is generally crystalline. FIG. 4 charts the amount of crystalline IrO₂ (110), in an IrOₓ film, as a function of the sputtering power, for four different sets of Ar/O₂ flow rate conditions. FIG. 4 shows that the largest amounts of amorphous IrOₓ was found when the sputtering power was set to approximately 1.2 kW, for all four sets of Ar/O₂ flow rates.

This experiment demonstrates that the desired sputtering conditions for forming an amorphous iridium oxide layer in a ferroelectric capacitor include using an O₂ flow rate of 20 sccm to 60 sccm, an argon gas flow rate of 20 sccm to 200 sccm, and a sputtering power between 0.8 kW and about 2.5 kW. This example, sputter conditions that were found to deposit the most amorphous iridium oxide occurred when the O₂ flow rate was 30 sccm, the argon flow rate was 100 sccm and sputtering power was 1 kW to 1.2 kW. Of course, sputtering powers outside the range of 1 kW to 1.2 kW, and deposition temperatures other than room temperature, will have different optimum Ar/O₂ flow rates to maximize the amount of amorphous iridium oxide deposited.

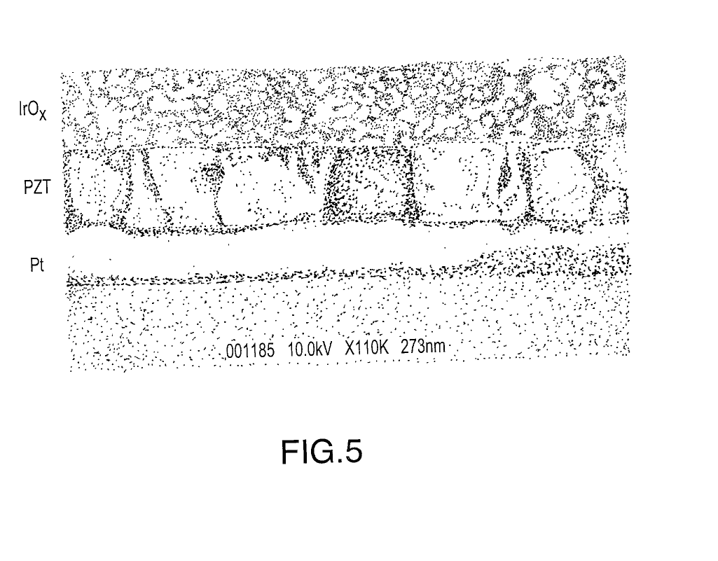

Referring now to FIG. 5, which a drawing of a top IrOx top electrode layer after anneal according to the present invention, it can be seen that the previously amorphous structure has been transformed into a polycrystalline structure. This structure has equiaxed grains of less than 30 nm.

While the invention has been particularly shown and described above with reference to a preferred embodiment, it should be understood by those skilled in the art that various other changes in the form and details may be made without departing from the spirit and scope of the invention.

We claim:

1. An integrated semiconductor device having a ferroelectric capacitor, wherein said ferroelectric capacitor comprises:
a protective layer comprising amorphous iridium oxide;
a top electrode that lies below the protective layer;
a ferroelectric dielectric layer that lies below the top electrode; and
a bottom electrode that lies below the ferroelectric dielectric layer.

2. The ferroelectric capacitor of claim 1, wherein said top electrode comprises amorphous iridium oxide, and the protective layer and the top electrode together form a single electrode.

3. The ferroelectric capacitor of claim 1, wherein said amorphous iridium oxide has an average grain size of 100 nm or less.

4. The ferroelectric capacitor of claim 1, wherein said protective layer has a thickness of 50 nm to 250 nm.

5. The ferroelectric capacitor of claim 4, wherein said protective layer has a thickness of 150 nm.

6. The ferroelectric capacitor of claim 1, wherein said top electrode is selected from the group consisting of Pt, Ir, RuO₂, SrRuO₃, LaSrCoO₃, and LaNiO₃.

7. The ferroelectric capacitor of claim 1, wherein said top electrode comprises crystalline IrO₂.

8. The ferroelectric capacitor of claim 1, wherein said ferroelectric dielectric layer comprises PZT.

9. The ferroelectric capacitor of claim 1, wherein said bottom electrode comprises platinum.

10. A ferroelectric capacitor that forms an element of an integrated semiconductor device, wherein said ferroelectric capacitor comprises:
a top electrode comprising amorphous iridium oxide that has an average grain size of 100 nm or less;
a ferroelectric dielectric layer, comprising PZT, that lies below the top electrode; and
a bottom electrode, comprising Pt, that lies below the ferroelectric dielectric layer.

11. A method of fabricating an integrated semiconductor device with ferroelectric capacitors comprising the steps of:
forming bottom electode;
forming a ferroelectric dielectric layer over the bottom electrode;
forming a top electrode over the ferroelectric dielectric layer; and
retaining an amorphous iridium oxide layer over the ferroelectric dielectric layer.

12. The method of claim 11, wherein the top electrode is selected from the group consisting of Pt, Ir, RuO₂, SrRuO₃, LaSrCoO₃, and LaNiO₃.

13. The method of claim 11, wherein said top electrode comprises crystalline IrO₂.

14. The method of claim 11, wherein said top electrode comprises amorphous iridium oxide, and the amorphous iridium oxide layer and the top electrode together form a single electrode.

15. An integrated semiconductor device having a ferroelectric capacitor, wherein said ferroelectric capacitor comprises:
a bottom electrode;
a ferroelectric dielectric layer formed over the bottom electrode; and
a top electrode formed over the ferroelectric dielectric layer,
wherein the ferroelectric dielectric layer was protected from chemical and mechanical degradation during fabrication of the integrated semiconductor device by a layer of amorphous iridium oxide.

16. A method of fabricating a protective layer of a ferroelectric capacitor comprising the steps of:
flowing a mixture of argon and oxygen gas across a metal sputtering target comprising iridium;
bombarding the sputtering target with argon ions in order to sputter iridium off of said target; and
depositing a layer of amorphous iridium oxide on top of a ferroelectric dielectric layer in order to form the protective layer.

17. The method of claim 16, wherein the protective layer is also the top electrode of the ferroelectric capacitor.

18. The method of claim 16, wherein the oxygen gas flows across the sputtering target at a rate of 20 sccm to 60 sccm.

19. The method of claim 18, wherein the oxygen gas flows across the sputtering target at a rate of about 30 sccm.

20. The method of claim 16, wherein the argon gas flow across the sputtering target at a rate of about 20 sccm.

21. The method of claim 16, wherein the sputtering target is bombarded with argon ions at a power of 0.8 kW to 2.5 kW.

22. The method of claim 21, wherein the sputtering target is bombarded with argon ions at a power of 1.2 kW.
